(19) United States
(12) Patent Application Publication
(10) Pub. No.: US 2014/0307430 A1
(43) Pub. Date: Oct. 16, 2014

(54) TRANSPARENT DISPLAY DEVICE AND TRANSPARENT DISPLAY PANEL

(71) Applicant: AU Optronics Corp., Hsin-Chu (TW)

(72) Inventors: Ching-Kai Lo, Hsin-Chu (TW); Hsueh-Yen Yang, Hsin-Chu (TW); Hsien-Hung Chen, Hsin-Chu (TW); Chun-Hsin Liu, Hsin-Chu (TW)

(73) Assignee: AU Optronics Corp., Hsin-Chu (TW)

(21) Appl. No.: 14/253,847

(22) Filed: Apr. 15, 2014

(30) Foreign Application Priority Data
Apr. 16, 2013 (TW) 102113522

(51) Int. Cl. G09F 13/00

(52) U.S. Cl. CPC G09F 13/00
USPC 362/231

(57) ABSTRACT

A transparent display device includes at least a first transparent display panel and a second transparent display panel, each of which has transparent regions and display regions. The arrangements of the transparent regions and display regions of the first transparent display panel and the second transparent display panel are opposite to each other. The transparent display device can apply a high transparency display mode or a lower transparency display mode by arranging the relative position of the first and second transparent display panels. In the lower transparency display mode, the first and second transparent display panels are at least partial overlapped with each other so as to display clear image with high definition.

### BACKGROUND OF THE INVENTION

1. Field of the Invention

The present invention relates to a transparent display device and a transparent display panel, and more particularly, to a transparent display device and a transparent display panel having transparent regions and display regions arranged in a specific arrangement so as to obtain enhanced display and transparent performance.

2. Description of the Prior Art

A transparent display generally refers to a display device which viewer can watch the image behind in the transparent state. The transparent display may be used in a showcase to display both a display image and materials behind the transparent display device. Many kinds of display panel with different technologies can be integrated with the transparent display device. Among the technologies, active matrix organic light emitting displays (AMOLEDs) have gained more and more attention due to further advantages of self-emitting light source, wide viewing angle, short response time, high emission rate, low operation voltage, small thickness, simple fabrication process, and having the possibility of being fabricated as flexible displays. Furthermore, the fabrication technology of AMOLEDs is gradually matured, thus transparent display devices with AMOLED technologies have been researched and developed continuously.

However, since the performance of both the transparent displaying state and the image displaying state have to be considered in the transparent display device, the arrangement of pixels of the transparent display panel has more problems relative to a traditional flat panel. These problems can result in unclear image, such as rough boundary of image. For example, the images in the conventional transparent display device have the common problem that they have rough fringes of image shapes. Furthermore, the displayed images of the conventional transparent display device are also interfered by the transparent displaying state, so that the conventional transparent display device cannot clearly show animations, movies, and photographs. Therefore, the application field of conventional transparent display device is restricted.

### SUMMARY OF THE INVENTION

It is one of the objectives of the present invention to provide a transparent display device and display panel which can provide preferable resolutions and clear images so as to improve issues of conventional transparent display device, such as unclarity and poor definition, caused by interferences of the transparent displaying state. Also, the transparent display device of the present invention is capable of being switched from a high transparency display mode to a lower transparency display mode, with a first transparent display panel overlapping with a second transparent display panel under the lower transparency display mode to provide clear images in a high resolution.

To achieve the purposes described above, the present invention provides a transparent display panel that includes a plurality of transparent regions and a plurality of display regions, and a plurality of first sub-pixels, a plurality of second sub-pixels and a plurality of third sub-pixels. Wherein, the transparent regions and the display regions are disposed in the transparent display panel, the transparent regions and the display regions are arranged alternately along a first direction. Each of the first sub-pixels, the second sub-pixels and the third sub-pixels is disposed in each one of the display regions respectively. The first sub-pixels are used for generating a first primary color light, the second sub-pixels are used for generating a second primary color light, and the third sub-pixels are used for generating a third primary color light. The first sub-pixels, the second sub-pixels and the third sub-pixels are arranged alternately along a second direction, within each of the corresponding display regions of the transparent display panel, wherein the first direction and the second direction intersect with each other. The display regions and the transparent regions are arranged in a plurality of columns or rows extending along the second direction. One of the first sub-pixels, one of the second sub-pixels and one of the third sub-pixels adjacent to each other in the transparent display panel are arranged in shape of delta arrangement.

To achieve the purposes described above, the present invention provides a transparent display device that comprises at least one first display panel and at least one second display panel. The first display panel includes a plurality of first transparent regions and a plurality of first display regions. The first transparent regions and the first display regions are arranged alternately in a plurality of rows or columns extending at least along a first direction. The first display panel has a first display area. The second display panel includes a plurality of second transparent regions and a plurality of second display regions. The second transparent regions and the second display regions are arranged alternately in a plurality of rows or columns extending at least along the first direction. The second display panel has a second display area. In a first display mode. The first display panel and the second display panel can be disposed parallel and side by side to compose a first display device having a third display area, so as to display a full image with the third display area, wherein the third display area is approximately equal to a sum of the first display area and the second display area. Further, in a second display mode, the first display panel and the second display panel can also be overlapped with each other to compose a second display device having a fourth display area, wherein each of the display regions of the first display panel is corresponding to one of the transparent regions of the second display panel respectively, and each of the transparent regions of the first display panel is corresponding to one of the display regions of the second display panel respectively. The fourth display area is approximately equal to an overlapping area of the first display area and the second display area.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic top view of a transparent display panel in accordance with a first embodiment of the present invention.

FIG. 2 illustrates a schematic top view of a transparent display panel in accordance with a second embodiment of the present invention.

FIG. 3 illustrates a schematic top view of a transparent display panel in accordance with a third embodiment of the present invention.

FIG. 4 to FIG. 6 illustrate schematic diagrams of a transparent display device in accordance with a fourth embodiment of the present invention.

FIG. 7 and FIG. 8 illustrate schematic diagrams of two operation modes of the transparent display device of the present invention.

FIG. 9 illustrates a schematic diagram of a transparent display device in accordance with a fifth embodiment of the present invention.

FIG. 10 illustrates a schematic diagram of a transparent display device in accordance with a sixth embodiment of the present invention.

FIG. 11 to FIG. 12 illustrate schematic diagrams of a transparent display device in accordance with a first variant embodiment of the fourth embodiment of the present invention.

FIG. 13 to FIG. 14 illustrate schematic diagrams of a transparent display device in accordance with a second variant embodiment of the fourth embodiment of the present invention.

FIG. 15 to FIG. 16 illustrate schematic diagrams of a transparent display device in accordance with a third variant embodiment of the fourth embodiment of the present invention.

FIG. 17 to FIG. 18 illustrate schematic diagrams of a transparent display device in accordance with a fourth variant embodiment of the fourth embodiment of the present invention.

FIG. 19 to FIG. 20 illustrate schematic diagrams of a transparent display device in accordance with a fifth variant embodiment of the fourth embodiment of the present invention.

### DETAILED DESCRIPTION

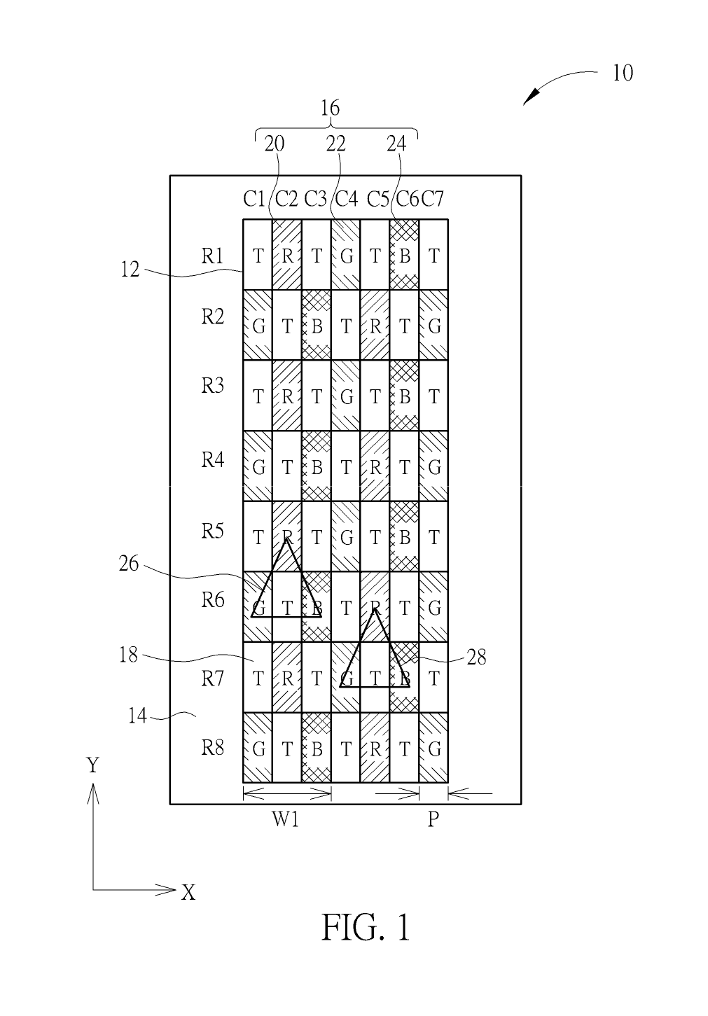

Referring to FIG. 1, FIG. 1 is a schematic top view of a transparent display panel in accordance with the first embodiment of the present embodiment. In the first embodiment, a transparent display panel 10 of the present invention optionally includes a display zone 12 and a peripheral zone 14. The display zone 12 includes a plurality of transparent regions 18 and a plurality of display regions 16 arranged alternately in the display zone 12, along a first direction (for example, Direction X or Direction Y as shown in FIG. 1), wherein the transparent regions 18 are shown as regions without shading in figures and have marked as “T”, and the display regions 16 are shown as regions with shading in figures. The display regions 16 refer to a sub-pixel part used for displaying images in a display panel. For instance, a switch circuit, a metal electrode, a light-emitting element or/and a color filter may be disposed in the display regions 16. One example of the light-emitting elements is an organic light emitting diode. However, the components and disposition of the display regions 16 are not limited to the above description. The transparent regions 18 refer to a nonluminous zone with film layer(s) having a high transmittance, allowing background images on any side of the transparent display panel 10 capable of being seen from the other side of the transparent display panel 10 via the transparent regions 18. However, the transparent regions 18 may also include a component used for displaying images or transferring signals. In an example, the transparent regions 18 and the display regions 16 are arranged alternately in a plurality of columns (including C1, C2, C3, C4 . . . ) extending along the Y Direction. In the present embodiment, the transparent regions 18 and the display regions 16 both have identical shape, being as a rectangle, but not limit thereto. As an example, if the first direction is the Y Direction in FIG. 1 the transparent regions 18 and display regions 16 are arranged alternately along the Y Direction, namely with the transparent regions 18 and the display regions 16 arranged alternately in each of the columns. For example, in the column C1, the transparent regions 18 are disposed in odd places corresponding to rows R1, R3, R5, R7 and R9, and the display regions 16 are disposed in even places corresponding to rows R2, R4, R6, R8 and R10. On the other hand, the transparent regions 18 and the display regions 16 are also arranged alternately in each row, such as R1, R2, R3 . . . R8, extending along a second direction (for example, the X Direction) . Accordingly, any one of the transparent regions 18 in the present embodiment is adjacent to at least two display regions 16, and is not adjacent to any other one of the transparent regions 18. Specifically, except for the periphery of the display zone 12, each transparent region 18 is adjacent to four display regions 16. Likewise, any one of the display regions 16 in the present embodiment is adjacent to at least two of the transparent regions 18, and is not adjacent to any other one of the other display regions 16. Also, except for the periphery of the display zone 12, each display region 16 is adjacent to four transparent regions 18.

Furthermore, the transparent display panel 10 further includes a plurality of first sub-pixels 20, a plurality of second sub-pixels 22 and a plurality of third sub-pixels 24. Each of the first sub-pixels 20, the second sub-pixels 22 and the third sub-pixels 24 is disposed in a corresponding display region 16 respectively. Among them, the first sub-pixels 20 are used for generating a first primary color light, such as red (being marked as R), the second sub-pixels 22 are used for generating a second primary color light, such as green (being marked as G), and the third sub-pixels 24 are used for generating a third primary color light, such as blue (being marked as B), but not limited thereto. The first sub-pixels 20, the second sub-pixels 22 and the third sub-pixels 24 are arranged alternately along the second direction, with each of them being disposed in the display regions 16 of the transparent display panel 10 respectively. The first direction intersects the second direction, and preferably the first direction is perpendicular to the second direction. As an example, if the first direction and the second direction are the X Direction and the Y Direction respectively, the display regions 16 in the row R1 extending along the X Direction will have one of the first sub-pixels 20, one of the second sub-pixels 22, one of the third sub-pixels 24 . . . sequentially and alternately. In addition, in the present embodiment, the display regions 16 arranged in each column along the Y Direction will have only one kind of the first sub-pixels 20, the second sub-pixels 22 and the third sub-pixels 24. With such arrangement, any one of the first sub-pixels 20 in one of the rows and one the second sub-pixels 22 and one of the third sub-pixels 24 adjacent to the one of the first sub-pixels 20 in another row adjacent to the one of the rows are arranged in a delta arrangement (such as in a shape of delta “A”), the deltas 26, 28 shown in FIG. 1 for example. In this way, a pixel consisted by one first sub-pixel 20, one second pixel 22 and one third pixel 24 will have a width “W1” in row direction, which can be regarded as a sum of width of two display regions 16 and one transparent region 18. Namely, the width “W1” of the pixel is three times of the width “P” of the display region 16 so that the transparent display panel 10 can achieve improved transparency effect, a high resolution and smoothness of shapes in images. In contrast, under the same fabrication level, a pixel consisted by each kind of sub-pixels in the conventional display panel needs to have a size at least in six times of the width of a sub-pixel. Therefore, the size of a pixel in the conventional transparent panel will at least be two times wider than that of the present invention, and the resolution of the conventional transparent panel will be half or less than half in comparison with that of the present invention.

The transparent display panel of the present invention and the transparent display deice comprising the transparent display panel of the present invention are not limited by the aforementioned embodiments, and may have other different preferred embodiments and variant embodiments. To simplify the description, the identical components in each of the following embodiments and variant embodiments are marked with identical symbols. For making it easier to compare the difference between the embodiments and variant embodiments, the following description will only detail the dissimilarities among different embodiments and variant embodiments and the identical features will not be redundantly described. Please note that the embodiments and variant embodiments are only an illustration to clarify the concept of the present invention, with numbers, arrangements and shapes of the transparent regions and the display regions in each display zone being not limited thereto.

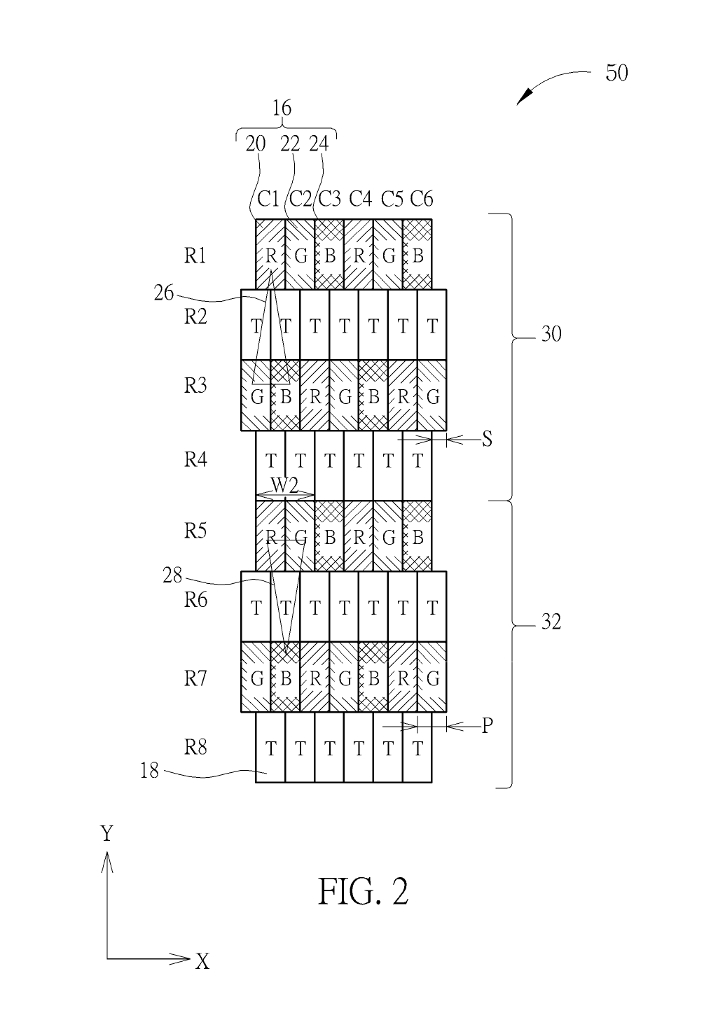

Referring to FIG. 2, FIG. 2 is a schematic top view of a transparent display panel in accordance with the second embodiment of the present invention. To simplify the description, only a display zone of the display panel has been illustrated in FIG. 2. In the present embodiment, an arrangement of display regions 16 and transparent regions 18 of the display panel 50 is different from that in the first embodiment of the present invention. In the present embodiment, the display regions 16 and the transparent regions 18 are arranged alternately along a first direction, wherein the first direction is the Y Direction shown in FIG. 2, for example. Along the Y Direction, two opposite sides (the upper side and the lower side) of any one of the transparent regions 18 are adjacent to the display regions 16 and which is not adjacent to any other one of the transparent regions 18. On the other hand, the first sub-pixels 20, the second sub-pixels 22 and the third sub-pixels 24 are arranged alternately along the X Direction which crosses the Y Direction, wherein each one of the first sub-pixels 20, the second sub-pixels 22 and the third sub-pixels 24 is disposed within the corresponding display region 16 respectively. Accordingly, in one row, such as the row R1, the first sub-pixels 20, the second sub-pixels 22 and the third sub-pixels 24 are arranged side by side alternately. Furthermore, the display regions 16 of the present embodiment are arranged in a plurality of first rows, such as R1, R3, R5, R7, extending along the X Direction, and the transparent regions 18 are arranged in a plurality of second rows, such as R2,R4, R6, R8, extending along the X Direction, wherein the first rows and second rows are arranged alternately along the Y Direction. In addition, the display regions 16 of the present embodiment have a width “P”, and the display regions 16 in any one of the first rows and the display regions 16 in another adjacent first row are shifted with a distance of 1/2 P. In other words, the shift distance “S” shown in the figure is half of the width “P”. For example, the first sub-pixels 20 in the first row R1 and the second sub-pixels 22 adjacent thereto in the first row R3 shift with a distance of 1/2 P in the X Direction. Similarly, the first sub-pixels 20 in the first row R1 and the third sub-pixels 24 adjacent thereto in the first row R3 also shift with a distance of 1/2 P in the X Direction. Besides, in another embodiment, the value of the shift distance S may be in a range between 0 and P based on any fabrication variation or any requirements of design. With such arrangement shown in FIG. 2, a pixel either consisted of one of the first sub-pixels 20 in the row R1 and one of the second sub-pixels 22 and one of the third sub-pixels 24 in the row R3, arranged in a delta 26 arrangement, or consisted of one of the first sub-pixels 20 in row R5, one of the second sub-pixels 22 in row R5 and one of the third sub-pixels 24 in row R7, arranged in a delta 28 arrangement, is obtained. Thus, in the present embodiment, one pixel in the X Direction has a width “W2,” regarded as two times of the width “P” of the display regions 16. In comparison with three to six times of width “P” for a pixel in the conventional transparent display panel, since the present embodiment space the first sub-pixels 20, the second sub-pixels 22 and the third sub-pixels 24 in adjacent row to obtain the first sub-pixels 20, the second sub-pixels 22 and the third sub-pixels 24 of one pixel arranged in a delta arrangement, the transparent display panel 50 can achieve higher resolution. It is noted that, in the present embodiment, four rows can be regarded as a unit . For example, rows R1, R2, R3, and R4 can be regarded as arranging unit 30, and rows R5, R6, R7 and R8 can be regarded as another arranging unit 32. Based on said principle, a size of the transparent display panel 50, as well as a number of the sub-pixels, can be further adjusted in accordance with practical requirements.

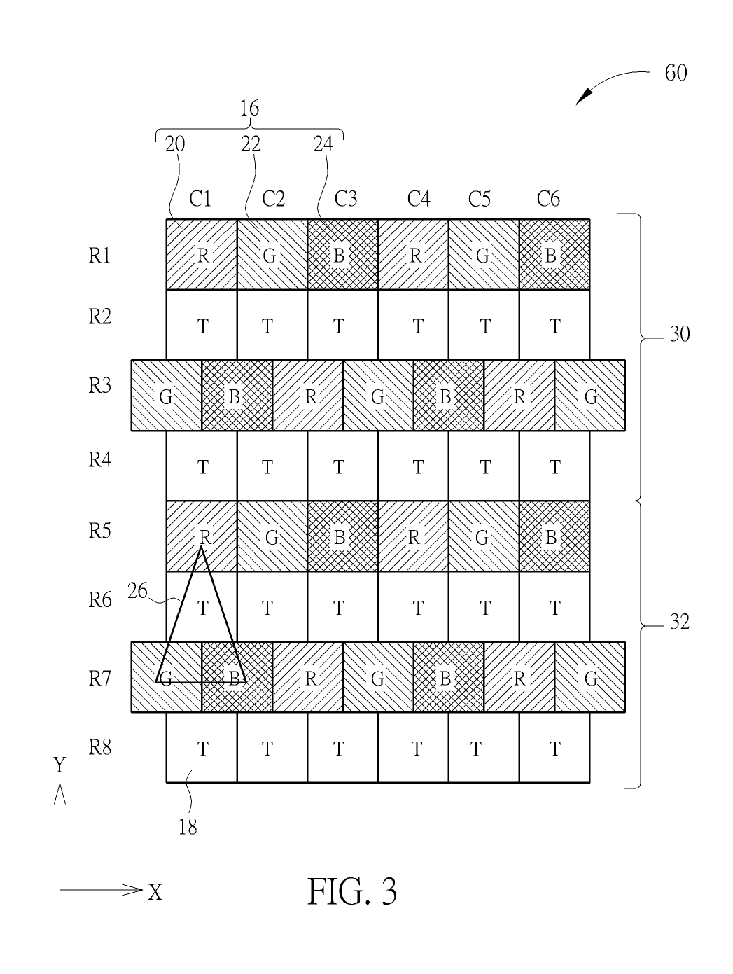

Referring to FIG. 3, FIG. 3 is a schematic top view of a transparent display panel in accordance with the third embodiment of the present invention. In the transparent display panel 60 of the present embodiment, one of the first sub-pixels 20 in one row and one second sub-pixel 22 and one of the third sub-pixel 24 in another row are also arranged in a delta arrangement, thereby functioning as a pixel. As an example, a first sub-pixel 20 of the first row R5, a second sub-pixel 22 and a third sub-pixel 24 of the first row R7 are arranged in a delta 26 shape. However, each of the display regions 16 and the transparent regions 18 are square, which is different from that of the second embodiment. With such design of having square display regions 16 and transparent regions 18 in the transparent display panel 60, a distance between adjacent first, second and third sub-pixels 20, 22, 24 in the Y Direction is shortened. Thus, a preferable display effect, such as a higher resolution and a smoother shape images viewed by the audience, can be obtained while the panel contains square display regions 16 and transparent regions 18 comparing to the equaled size panel contains the other kind shape of display regions and transparent regions.

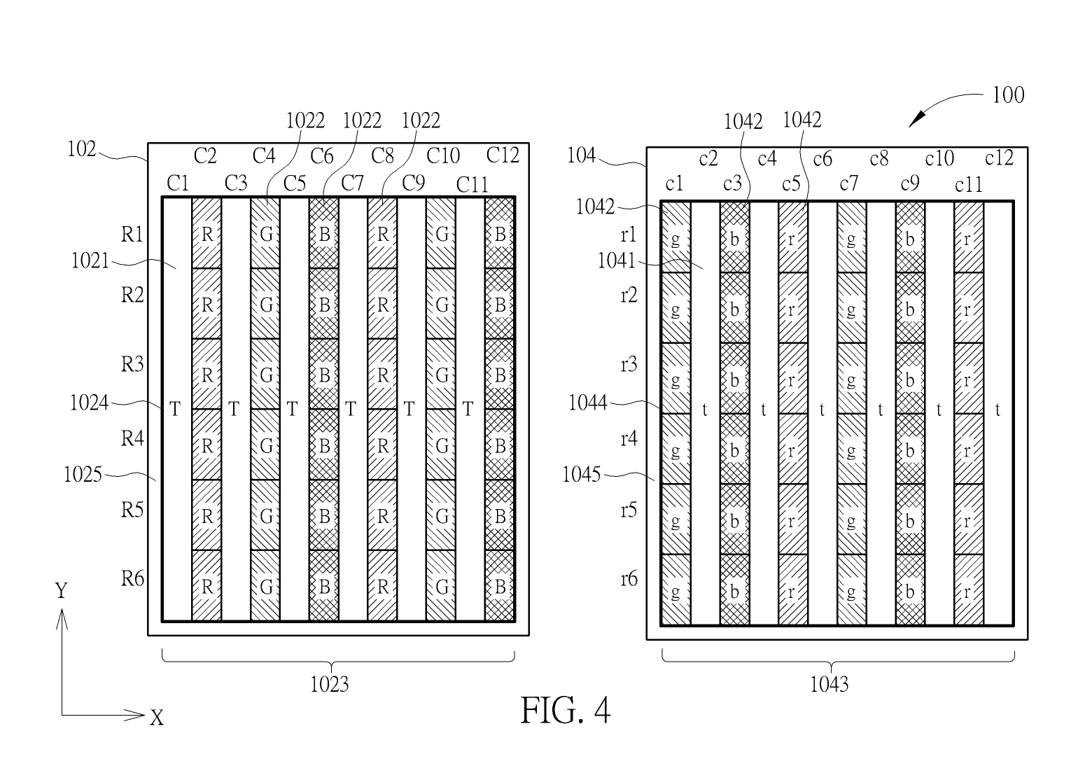

FIG. 4 to FIG. 6 are schematic diagrams of a transparent display device in accordance with a fourth embodiment of the present invention. Referring to FIG. 4, the transparent display device 100 of the present invention has two transparent display panels, being a first transparent display panel 102 and a second transparent display panel 104. Similar to what is disclosed above about the transparent display panel of the present invention, the first transparent display panel 102 includes a display zone 1024 and a peripheral zone 1025. The display zone 1024 includes a plurality of first transparent regions 1021 and a plurality of first display regions 1022 (with the first transparent region 1021 being marked as “T”) disposed therein. The second transparent display panel 104 also includes a display zone 1044 and a peripheral zone 1045, and the display zone 1044 includes a plurality of second transparent regions 1041 and a plurality of second display regions 1042 (with the second transparent region 1041 being marked as “t”) . In view of the first transparent display panel 102, the first transparent regions 1021 and the first display regions 1022 are arranged alternately at least along a first direction and are arranged in a plurality of columns or rows respectively extending along a second direction. For example, in the present embodiment, the X Direction is regarded as the first direction, and the Y Direction is regarded as the second direction, thus the first transparent regions 1021 and the first display regions 1022 are arranged alternately in a plurality of columns (including C1, C2, C3 . . . C12) along the X Direction, with each column extending along the Y Direction. The first transparent display panel 102 has a first display area 1023, being approximately equal to an area of the display zone 1024. On the other hand, the second display regions 1042 and the second transparent regions 1041 of the second transparent display panel 104 are arranged alternately at least along the X Direction and are respectively arranged in a plurality of columns, such as c1, c2, c3 . . . c12, extending along the Y Direction. The second transparent display panel 104 has a second display area 1043, being approximately equal to an area of the display zone 1044. In the present embodiment, the first display area 1023 is approximately equal to the second display area 1043, and the total area (or occupation area ratio) of the first display regions 1022 in the display zone 1024 is approximately equal to that of the second display regions 1042 in the display zone 1044. However, a position of first display regions 1022 within the first display zone 1024 is opposite to that of the second display regions 1042 in the second display zone 1044. According to FIG. 4, the first display regions 1022, the first transparent regions 1021, the second display regions 1042 and the second transparent regions 1041 are all in rectangular shapes, while the first transparent regions 1021 and the second transparent regions 1041 are more like strips in particular.

Furthermore, the first transparent display panel 102 further includes a plurality of first sub-pixels “R”, a plurality of second sub-pixels “G”, and a plurality of third sub-pixels “B”, and each of the first sub-pixels “R”, the second sub-pixels “G” and the third sub-pixels “B” is disposed in one of the first display regions 1022 respectively. Likewise, the second transparent display panel 104 further includes a plurality of first sub-pixels “r”, a plurality of second sub-pixels “g”, and a plurality of third sub-pixels “b”, and each of the first sub-pixels “r”, the second sub-pixels “g” and the third sub-pixels “b” is disposed in one of the second display regions 1042 respectively. In the first transparent display panel 102 and the second transparent display panel 104, the first sub-pixels “R” and “r” are used for generating a first primary color light, such as red, the second sub-pixels “G” and “g” are used for generating a second primary color light, such as green, and the third sub-pixels “B” and “b” are used for generating a third primary color light, such as blue, but not limited thereto. In the present embodiment, the first sub-pixels “R”, the second sub-pixels “G” and the third sub-pixels “B” of the first transparent display panel 102 are arranged in a plurality of columns (including C2, C4, C6, C8, C10, C12) extending along the Y Direction respectively, and the first sub-pixels “R”, the second sub-pixels “G” and the third sub-pixels “B” are arranged by turns and alternately along the X Direction. Likewise, the second sub-pixels “g”, the third sub-pixels “b” and the first sub-pixels “r” of the second transparent display panel 104 are arranged in a plurality of columns (including c1, c3, c5, c7, c9, C11) extending along the Y Direction respectively, and the second sub-pixels “g”, the third sub-pixels “b” and the first sub-pixels “r” are arranged by turns and alternately along the X Direction.

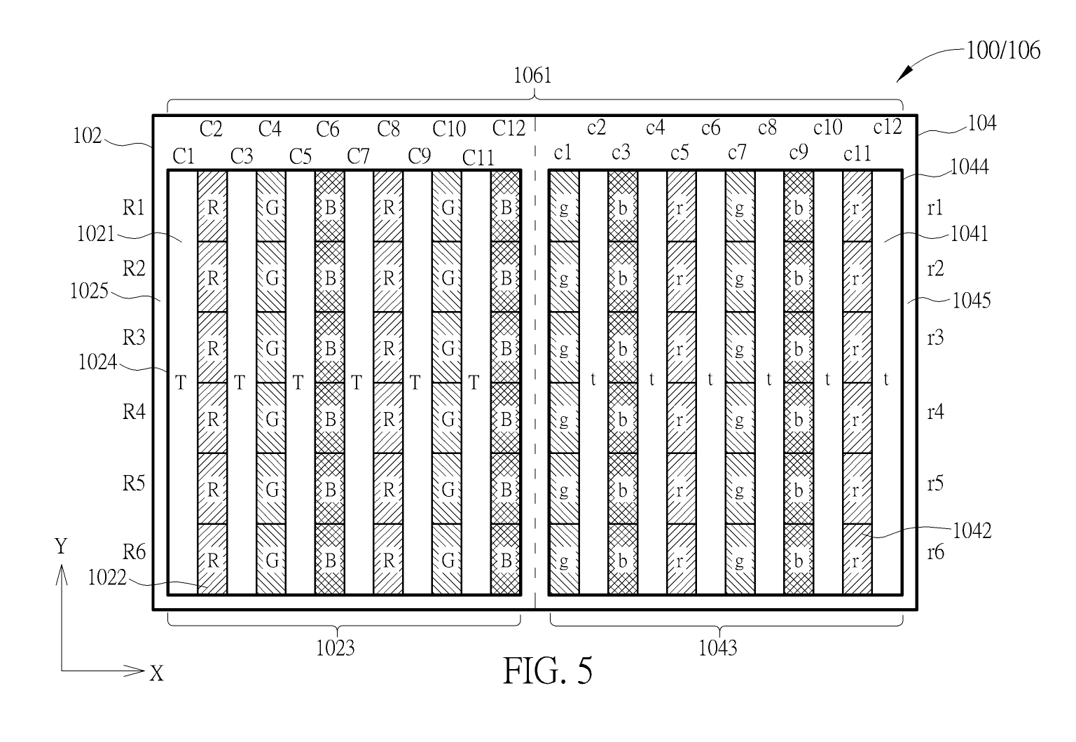

Referring to FIG. 5, the transparent display device 100 of the present invention can have a first display mode, for example a transparent display mode by enabling the first transparent display panel 102 and the second transparent display panel 104 to be arranged parallel and side by side to compose a first display device 106, so as to display a full image having a third display area 1061. The third display area 1061 is approximately equal to a sum of the first display area 1023 and the second display area 1043, or is approximately two times of the first transparent display panel 102 or the second transparent display panel 104. Since the first transparent regions 1021, the first display regions 1022, the second transparent regions 1041 and the second display regions 1042 of the first display device 106 are arranged alternately along the X Direction, the first display device 106 is capable of displaying images with transparency effect.

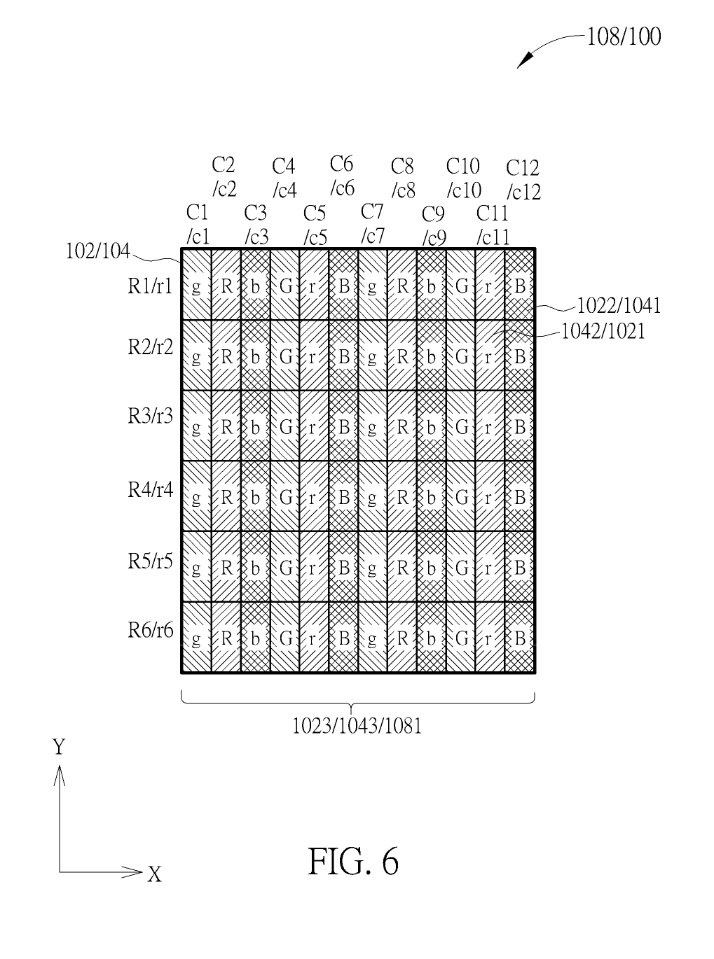

Next, with reference to FIG. 6, FIG. 6 is a schematic diagram of the transparent display device 100 of the present invention under a second display mode, wherein the peripheral zone is omitted to simplify the description and figure. The transparent display device 100 of the present invention also has the second display mode by enabling the first transparent display panel 102 and the second transparent display panel 104 to overlap with each other to compose a second display device 108 having a fourth display area 1081. The fourth display area 1081 is approximately equal to an overlapping area between the first display area 1023 and the second display area 1043. In the present embodiment, the fourth display area 1081 is approximately equal to the first display area 1023 or the second display area 1043. In the second display device 108, each of the first display regions 1022 of the first display panel 102 is corresponding to one of the transparent regions 1041 of the second display panel 104, and each of the transparent regions 1021 of the first display panel 102 is corresponding to one of the display regions 1042 of the second display panel 104 respectively. Furthermore, in the second display device 108, the first sub-pixels “R”, the third sub-pixels “b”, the second sub-pixels “G”, the first sub-pixels “r”, the third sub-pixels “B” and the second sub-pixels “g” are arranged alternately by turns along the X Direction. While the second display device 108 displays images colors displayed by the second display regions 1042 of the second transparent display panel 104 can be seen through the first transparent regions 1021 of the first transparent display panel 102, by taking the disposition as an example that the first transparent display panel 102 is disposed above the second transparent display panel 104. Thus, through the overlapped first and second transparent display panels 102, 104, the display functions of showing poor transparency or non-transparency images can be provided in the present embodiment. Accordingly, it is noted that images displayed by the first display device 106 have a higher transparency, in comparison with that of the images displayed by the second display device 108. Namely, the second display mode is a lower transparency display mode, and the first display mode is a high transparency display mode.

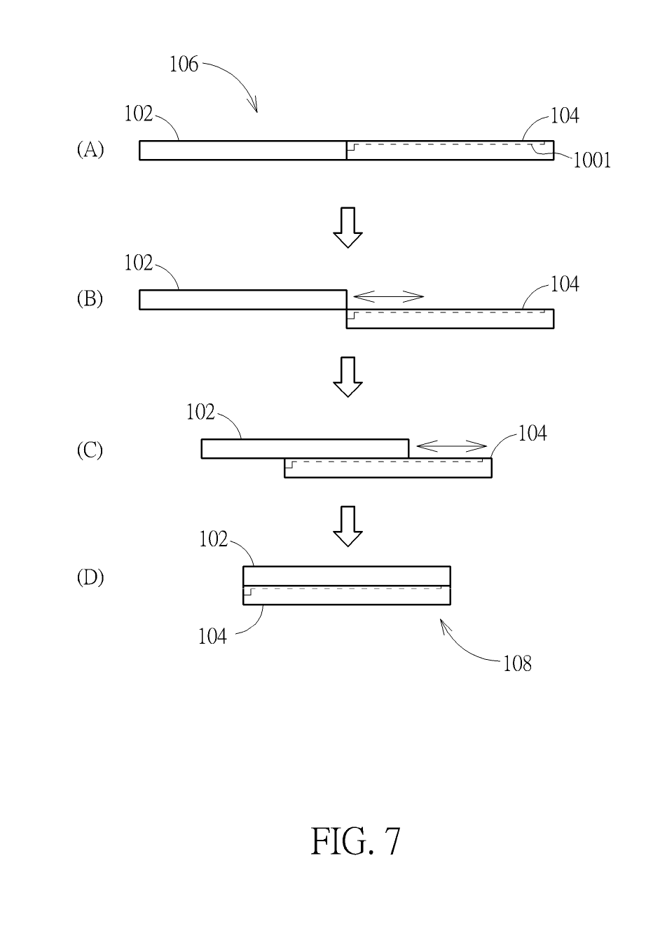

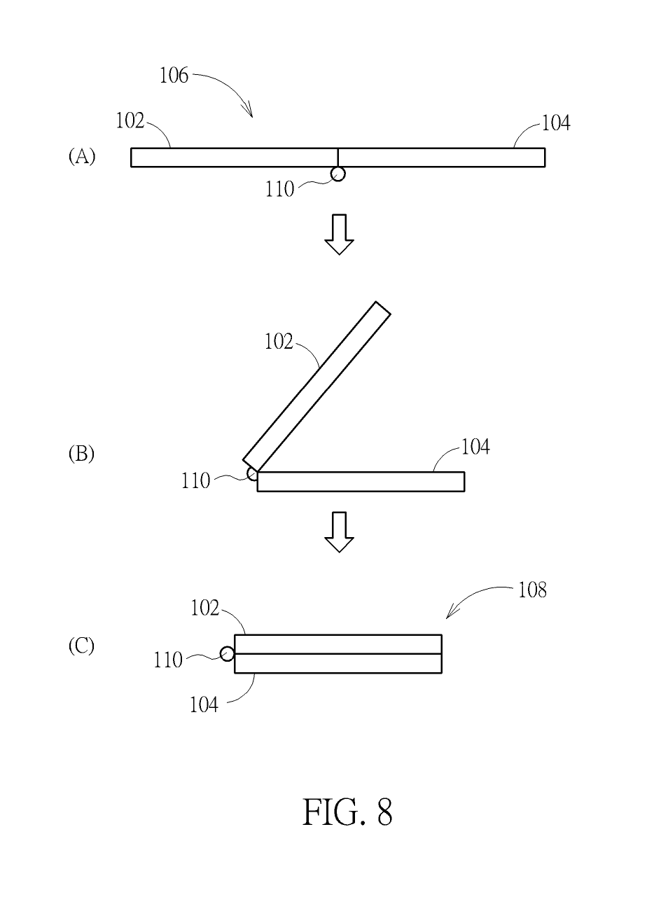

FIG. 7 and FIG. 8 are schematic diagrams of two operations of the transparent display device 100 of the present invention. With reference to FIG. 7, the transparent display device 100 may optionally include a slide mechanism 1001 disposed on at least one of the first display panel 102 and the second display panel 104. Assuming the slide mechanism 1001 is disposed on the second transparent display panel 104 as an example, the first transparent display panel 102 is capable of moving forward and backward along a direction (shown as the thin arrow in FIG. 7) via the slide mechanism 1001. In the state (A) shown in FIG. 7, the first and second transparent display panels 102, 104 can be arranged parallel and side by side to compose the first display device 106 under the first display mode of a high transparency, so that which can display transparent images. While switching to the second display mode of a lower transparency, the first transparent display panel 102 can be moved upward at first as shown in the state (B), followed by moving the first transparent display panel 102 parallel via the slide mechanism 1001 as shown in the state (C) and moving the first transparent display panel 102 till a surface of the second transparent display panel 104 is complete covered by the first transparent display panel 102 as shown in a state (D), so as to compose the second display device 108 for displaying lower transparency images. Referring to FIG. 8, in another example, the transparent display device 100 may optionally include a pivot mechanism 110 disposed between the first and second transparent display panels 102, 104, such that one of the first and the second display panels 102, 104 arranged in parallel and side by side is capable of turning over on a surface of the other one of the first and second display panels 102, 104 through the pivot mechanism 110, thereby composing the second display device 108. As shown in the state (A) of FIG. 8, the first and the second transparent display panels 102, 104 of the first display device 106 are disposed parallel and side by side at first. While switching to the second display mode with a lower transparency, the first transparent display panel 102 is turned over by taking the pivot mechanism 110 as a turning center, as shown in the state (B) in FIG. 8, till that a surface of the second transparent display panel 104 is complete covered by the first transparent display panel 102 as shown in the state (C), thereby composing the second display device 108. It is noted that, in the present example, the first transparent display panel 102 is preferably a double-side light-emitting display panel.

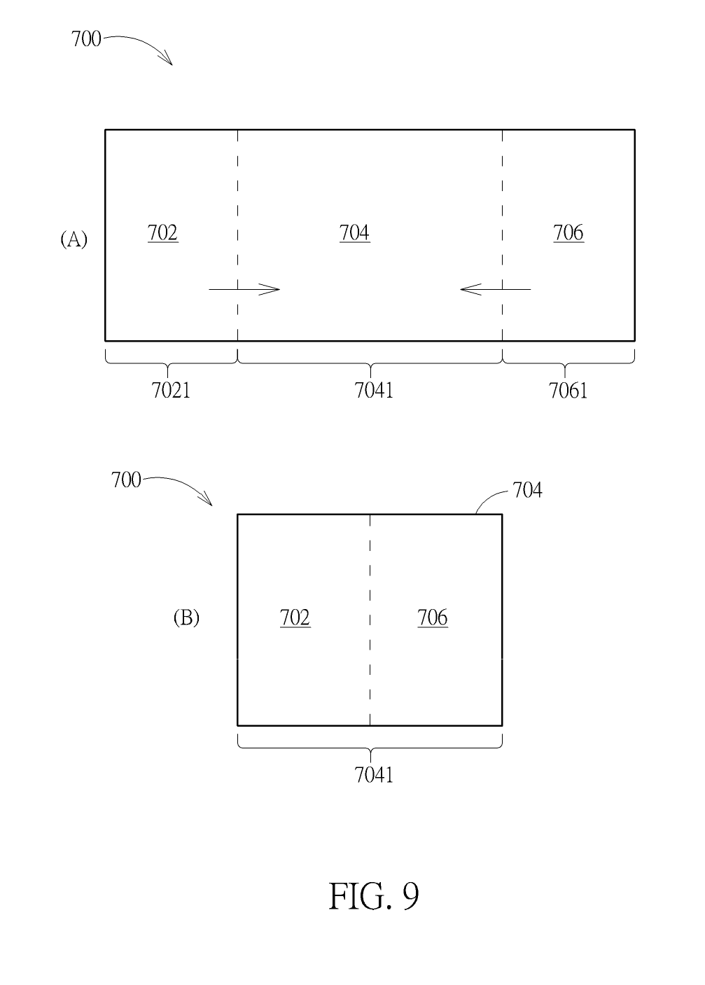

Referring to FIG. 9, FIG. 9 is a schematic diagram of a transparent display device in accordance with the fifth embodiment of the present invention. A transparent display device 700 of the fifth embodiment of the present invention includes a first transparent display panel 702, a second transparent display panel 704 and a third transparent display panel 706 having a first display area 7021, a second display area 7041 and a third display area 7061 respectively, wherein the second display area 7041 is approximately equal to a sum of the first display area 7021 and the third display area 7061. The arrangement of the transparent regions and sub-pixels of the first transparent display panel 702 and the third transparent display panel 706 may be similar to that of the first transparent display panel 102 in the fourth embodiment, and the arrangement of the transparent regions and sub-pixels of the second transparent display panel 704 may be similar to that of the second transparent display panel 104. With such arrangement, while the transparent display device 700 is under the first display mode, the first transparent display panel 702, the second transparent display panel 704 and the third transparent display panel 706 can be disposed side by side to provide a function of displaying images with good transparency. With reference to the state (A) in FIG. 9, a display area of the transparent display device 700 is approximately equal to a sum of the first display area 7021, the second display area 7041 and the third display area 7061. While switching to the second display mode, the first transparent display panel 702 and the third transparent display panel 706 will be moved along the directions shown as the arrows via a slide mechanism, a pivot mechanism or other suitable mechanisms, till covering on a top of the second transparent display panel 704, as shown in the state (B), so that the transparent regions of the second transparent display panel 704 are corresponding to the display regions of the first and third transparent display panels 702, 706 to display nontransparent images. The area of the nontransparent images is approximately equal to the third display area 7041.

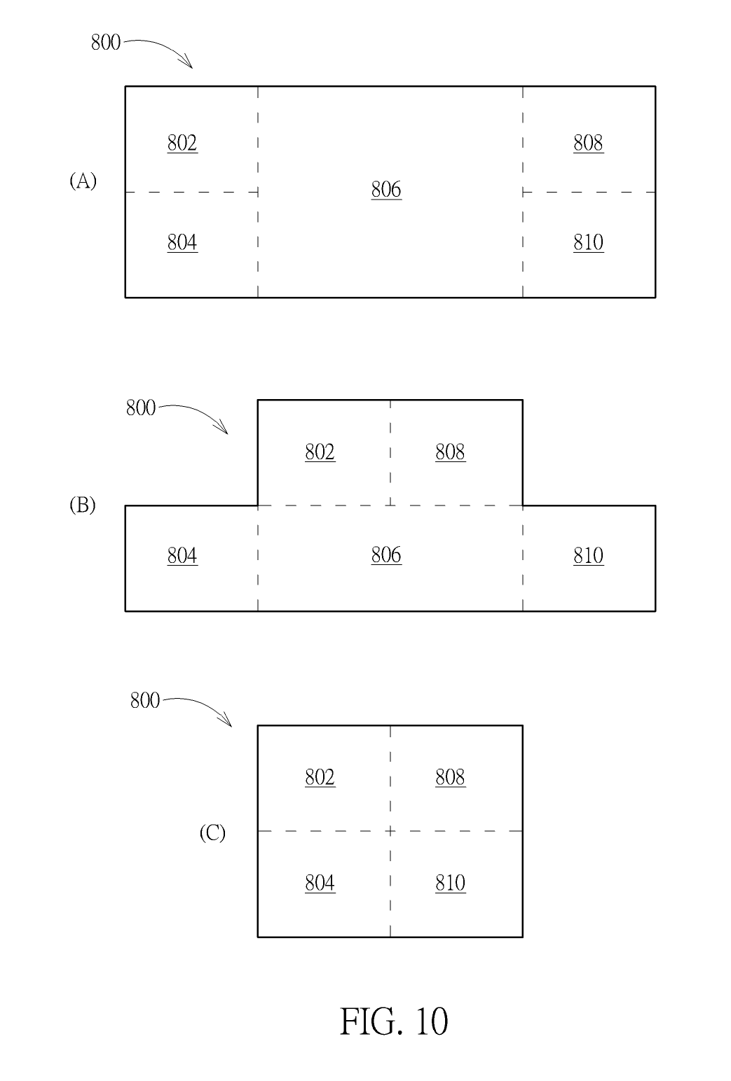

Referring to FIG. 10, FIG. 10 is a schematic diagram of a transparent display device in accordance with the sixth embodiment of the present invention. A transparent display device 800 of the sixth embodiment of the present invention includes a first transparent display panel 802, a second transparent display panel 804, a third transparent display panel 806, a fourth transparent display panel 808 and a fifth transparent display panel 810, having a first display area, a second display area, a third display area, a fourth display area and a fifth display area respectively. The first, the second, the fourth and the fifth display areas may be approximately identical, and a sum thereof may be approximately equal to the third display area. While under the first display mode, the first, the second, the third, the fourth and the fifth transparent display panels 802, 804, 806, 808, 810 are disposed side by side to provide a function of displaying images with good transparency, as being shown in the state (A) of FIG. 10. If a partial transparent display function is requested, a surface of the third transparent display panel 806 can also be partially covered by the other one or more display panels. As being shown in the state (B), the first and the fourth transparent display panels 802, 808 may be disposed to partially overlap the third transparent display panel 806, with an overlapped portion thereof displays non-transparent images. While under the second display mode, the first, the second, the fourth and the fifth transparent display panels 802, 804, 808, 810 can be disposed on a surface of the third transparent display panel 806, as shown in the state (C). An arrangement of the transparent regions, the display regions and the sub-pixels in the first, the second, the third, the fourth and the fifth transparent display panels 802, 804, 806, 808, 810 can be designed with reference to what is disclosed in the transparent displays of the fourth embodiment, the fifth embodiment and their variant embodiments of the present invention, and will not be further detail herein.

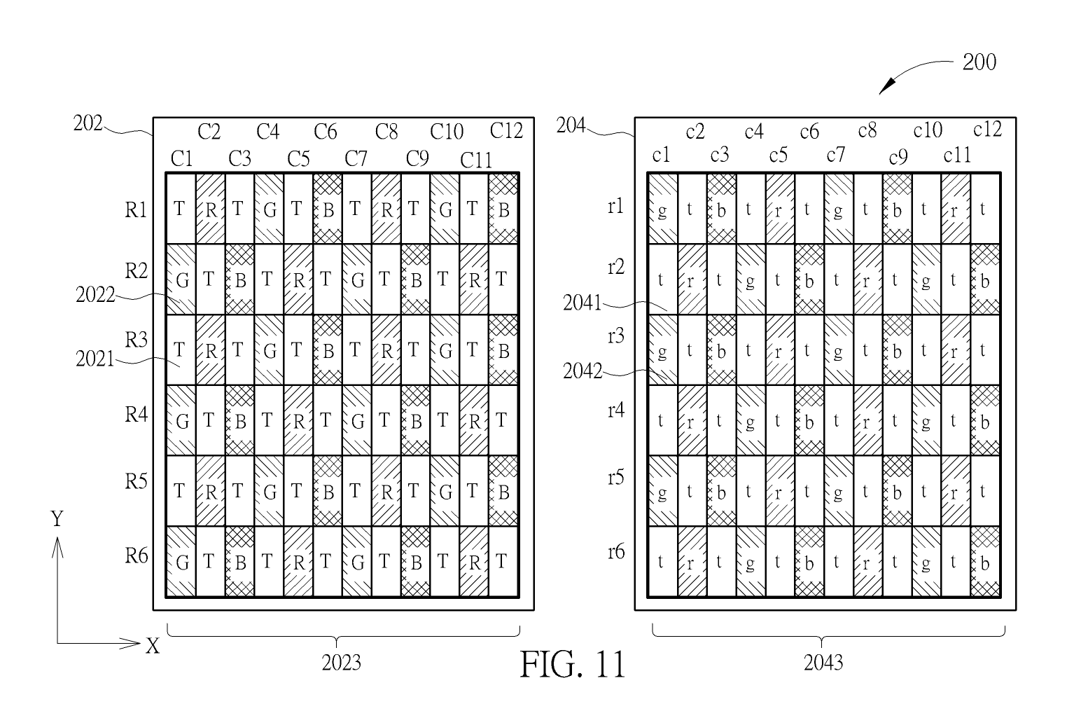

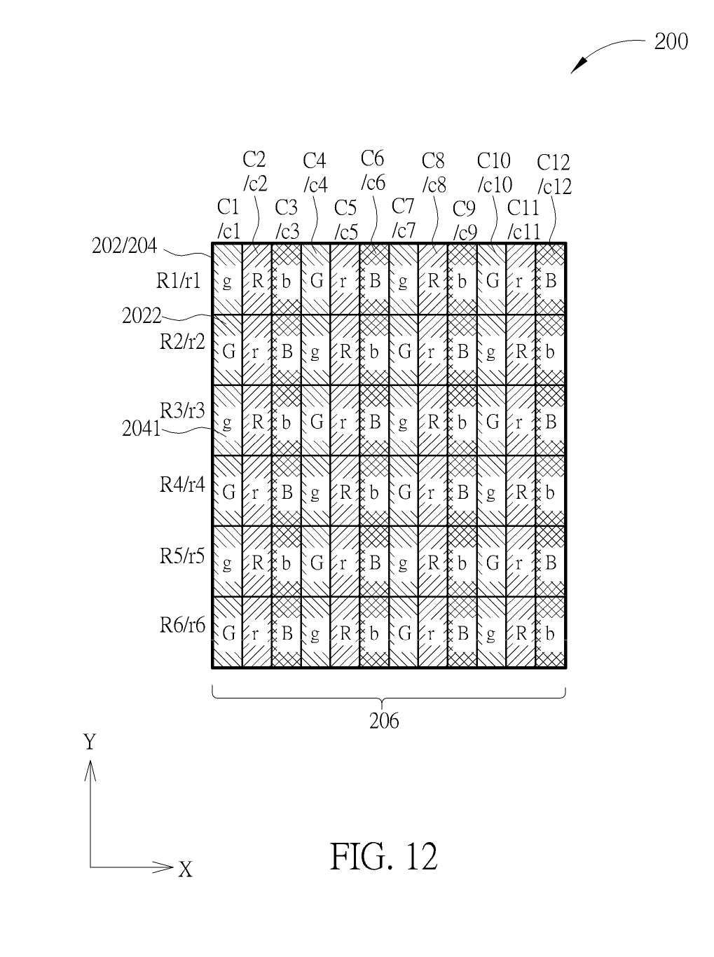

In the following, the arrangements of the transparent regions and the display regions, as well as the sub-pixels of the transparent display device of the present invention are further described. Referring to FIG. 11 to FIG. 12, FIG. 11 to FIG. 12 are schematic diagrams of a transparent display device in the first variant embodiment of the fourth embodiment of the present invention. As shown in FIG. 11, a transparent display device 200 of the present variant embodiment includes a first transparent display panel 202 and a second transparent display panel 204, with each of them having a first display area 2023 and a second display area 2043 respectively. Please noted that, differences between the present variant embodiment and FIG. 4 is characterized in the arrangement of the sub-pixels and transparent regions in the first and the second transparent display panels 202, 204. In the first transparent display panel 202, the first transparent regions 2021 and the first display regions 2022 are arranged alternately in a plurality of columns (such as C1, C2, C3 . . . C12) extending along the Y Direction, and which are also arranged alternately in a plurality of rows (such as R1, R2, R3 . . . R6) extending along the X Direction. Accordingly, any one of the first transparent regions 2021 is adjacent to at least two of the first display regions 2022 but is not adjacent to any other one of the first transparent regions 2021. In addition, in each column extending along the Y Direction, the first display regions 2021 only have one kind of the first sub-pixels “R”, the second sub-pixels “G” and the third sub-pixels “B” . As an example, the first display regions 2021 in column Cl only include the second sub-pixels “G” respectively, and the first display regions 2021 in column C2 only include the first sub-pixels “R” respectively. Furthermore, the first sub-pixels “R”, the second sub-pixels “G” and the third sub-pixels “B” are arranged alternately along the X Direction. In row R1 for example, the transparent region T, the first sub-pixel “R”, the transparent region “T”, the second sub-pixel “G”, the transparent region “T”, the third sub-pixel “B”, transparent region “T”, the first sub-pixel “R”. . . are arranged sequentially alternately. Likewise, in the second transparent display panel 204, the second display regions 2042 and the second transparent regions 2041 are arranged alternately in a plurality of columns (such as c1, c2, c3 . . . c12) extending along the Y Direction, and which are also arranged alternately in a plurality of rows (such as r1, r2, r3 . . . r6) extending along the X Direction. Accordingly, any one of the second transparent regions 2041 is adjacent to at least two of the second display regions 2042 but is not adjacent to any other one of the second transparent regions 2041. Also, in each column extending along the Y Direction, the second display regions 2042 have only one kind of the first sub-pixels “r”, the second sub-pixels “g” and the third sub-pixels “b”. Furthermore, the second sub-pixels “g”, the third sub-pixels “b” and the first sub-pixels “r” are arranged alternately along the X Direction. Under the first display mode, the first and the second transparent display panels 202, 204 can be disposed side by side to compose a first display device with a high transparency and to display images at the same time, wherein a display area of the first display device is approximately equal to a sum of the first and second display areas 2023, 2043. Referring to FIG. 12, under the second display mode, the first and the second transparent display panels 202, 204 can be disposed to overlap with each other to compose a second display device for displaying images with a lower transparency, so that the first transparent regions 2021 are corresponding to the second display regions 2042, and the first display regions 2022 are corresponding to the second transparent regions 2041. Thus, the second sub-pixels “g”, the first sub-pixels “R”, the third sub-pixels “b”, the second sub-pixels “G”, the first sub-pixels “r” and the third sub-pixels “B” in each row are arranged sequentially alternately along the X Direction to compose pixels. Therefore, a display area 206 of the transparent display device 200 is approximately equal to the first display area 2023 or the second display area 2043.

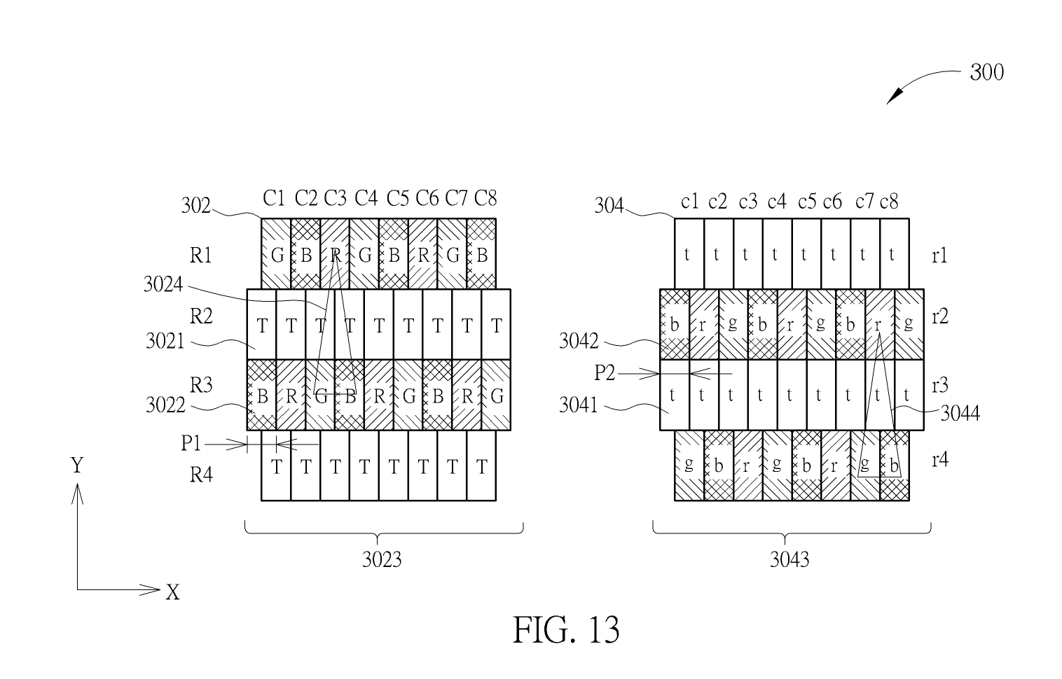

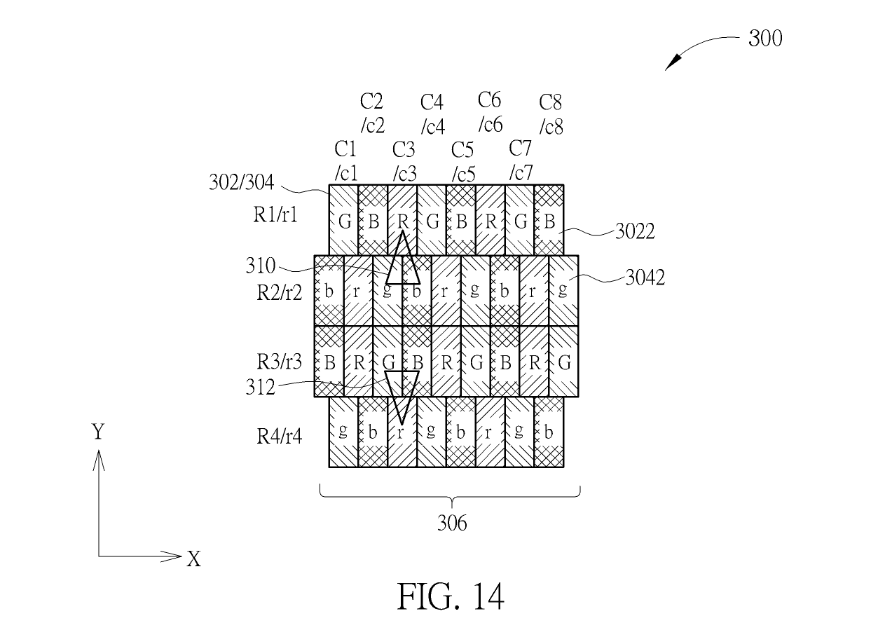

FIG. 13 and FIG. 14 are schematic diagrams of a transparent display device in a second variant embodiment of the fourth embodiment of the present invention. To simplify the description, the peripheral zone is not shown and only a partial display zone of the transparent display panel is illustrated in FIG. 13 and FIG. 14. Referring to FIG. 13, a transparent display device 300 of the present second variant embodiment includes a first transparent display panel 302 and a second transparent display panel 304 having a first display area 3023 and a second display area 3043 respectively. In the first transparent display panel 302, a plurality of first display regions 3022 are arranged side by side in a plurality of first rows (such as R1, R3) extending along the X Direction, and a plurality of first transparent regions 3021 are arranged side by side in a plurality of second rows (such as R2, R4) extending along the X Direction, wherein the first rows R1, R3 and the second rows R2, R4 are arranged alternately along the Y Direction. In the same first row, the first row R1 for example, the first sub-pixels “R”, the second sub-pixels “G” and the third sub-pixels “B” are arranged alternately along the X Direction, and any one of the first sub-pixels “R” in the first row and one of the second sub-pixels “G” and one of the third sub-pixels “B” in another adjacent first row are arranged in a delta arrangement, such as the delta 3024 shown in figures. Similarly, in the second transparent display panel 304, a plurality of second transparent region 3041 are arranged side by side in a plurality of third rows (such as r1, r3) extending along the X Direction, and a plurality of second display regions 3042 are arranged side by side in a plurality of fourth rows (such as r2, r4) extending along the X Direction, wherein the third rows r1, r3 and the fourth rows r2, r4 are arranged alternately along the Y Direction. In the same fourth row, the first sub-pixels “r”, the second sub-pixels “g” and the third sub-pixels “b” are arranged alternately along the X Direction, and anyone of the first sub-pixels “R” in the fourth row (such as r2) and one of the second sub-pixels “g” and one of the third sub-pixels “b” in another adjacent fourth row (such as r4) are arranged in a delta arrangement, such as the delta 3044 shown in FIG. 13. Moreover, the first display regions 3022 and the second display regions 3042 have a first width P1 and a second width P2 respectively, and the first display regions 3022 and the second display regions 3042 are arranged irregularly, the first display regions 3022 in one of the first rows (such as R1) are shifted relative to the first display regions 3022 in another adjacent first row (such as R3) in a distance of half of the first width P1, and the second display regions 3042 in one of the fourth rows (such as r2) are shifted relative to the second display regions 3042 in another adjacent fourth row (such as r4) in a distance of half of the second width P2. With such dislocated arrangement, the resolution of displayed images can be improved. In addition, since the first and second transparent regions 3021, 3041 of the present variant embodiment are located in the second and third rows, a preferable transmittance can be obtained to the transparent display device 300 under the first display mode.

Referring to FIG. 14, in the second display mode, the first and the second transparent display panels 302, 304 are overlapped with each other to compose a second display device 306, wherein the display area of the second display device 306 is approximately equal to the overlapping area between the first and the second display areas 3023, 3043. For example, the display area of the second display device 306 maybe approximately equal to the first display area 3023 or the second display area 3043. In this situation, the fourth rows r2, r4 and the first rows R1, R3 are arranged alternately along the Y Direction, and anyone of the first sub-pixels “R” in one of the first rows (such as R1) and one of the second sub-pixels “g” and one of the third sub-pixels “b” in an adjacent fourth row (such as r2) are arranged in a delta arrangement, such as the delta 310 shown in FIG. 14. On the other hand, any adjacent second sub-pixel “G” and third sub-pixel “B” in one of the first rows (such as R3) and one adjacent first sub-pixel “r” in an adjacent fourth row (such as r4) are also arranged in a delta arrangement, as the delta 312 shown in FIG. 14.

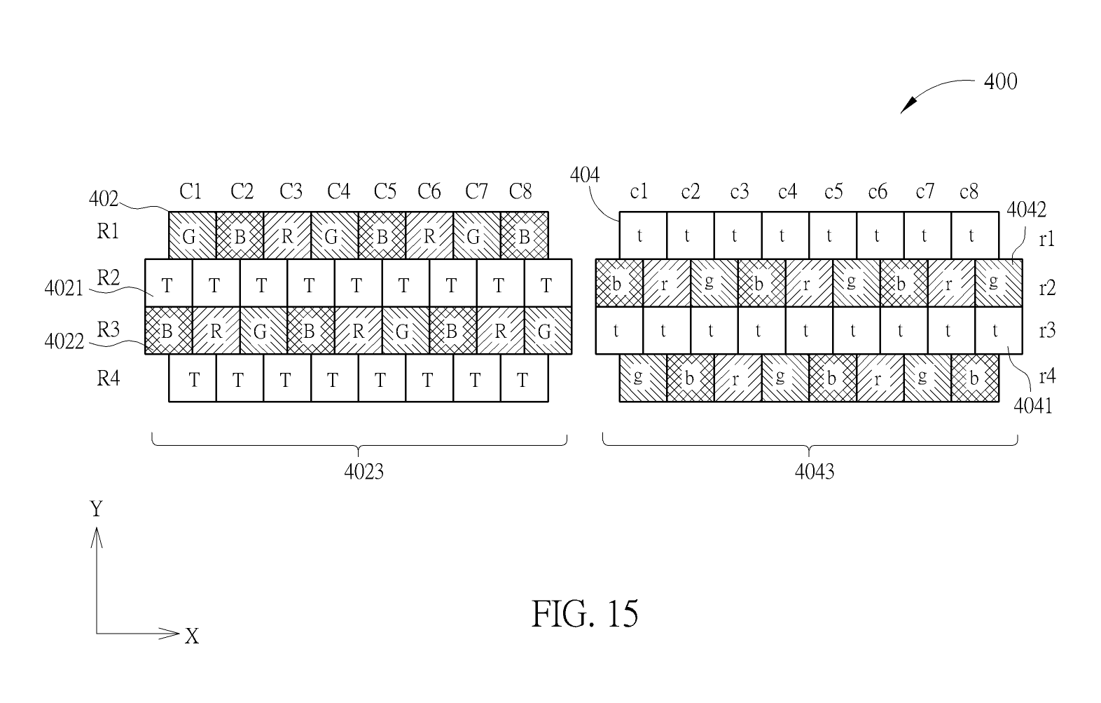

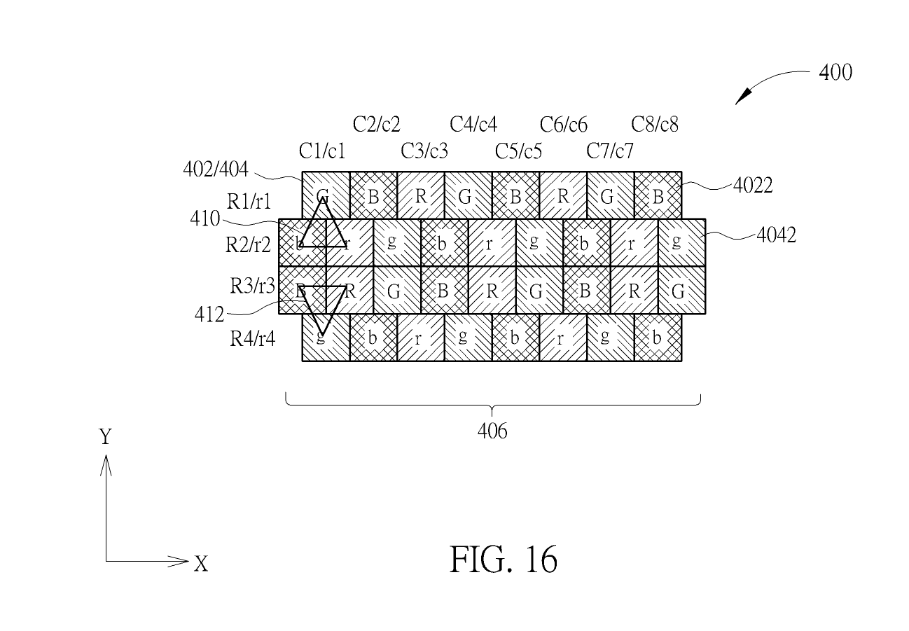

FIG. 15 to FIG. 16 are schematic diagrams of a transparent display device in a third variant embodiment of the fourth embodiment of the present invention. To simplify the description, the peripheral zone is not shown and only a partial display zone of the transparent display panel is illustrated in FIG. 15 and FIG. 16. Referring to FIG. 15, a transparent display device 400 of the present third variant embodiment includes a first transparent display panel 402 and a second transparent display panel 404, having a first display area 4023 and a second display area 4043 respectively. The first transparent display panel 402 includes a plurality of first transparent regions 4021 and a plurality of first display regions 4022, and the second transparent display panel 404 includes a plurality of second transparent regions 4041 and a plurality of first display regions 4042. However, the difference between the second variant embodiment and the third variant embodiment of the fourth embodiment is that the first transparent regions 4021, the first display regions 4022, the second transparent regions 4041 and the second display regions 4042 are square in shapes. As shown in FIG. 16, while the first and the second transparent display panels 402, 404 are overlapped with each other to compose a second display device 406 can be composed, wherein any one of the second sub-pixels “G” in one of the rows (such as the first row R1) and one of the third sub-pixel “b” and one of the first sub-pixel “r” in another adjacent row (such as the fourth row r2) are arranged in a delta arrangement, such as the deltas 410, 412 shown in FIG. 16. Since the first and second display regions 4022, 4042 are in square, the problems due to far displaying distance caused by rectangular sub-pixels can be further improved. For example, if the first and second display regions 4022, 4042 in the present variant embodiment have the same areas as that of the first and second display regions 3022, 3042 in the second variant embodiment but are different in shape from the first and second display regions 3022, 3042, a superior display effect will be achieved in the present variant embodiment.

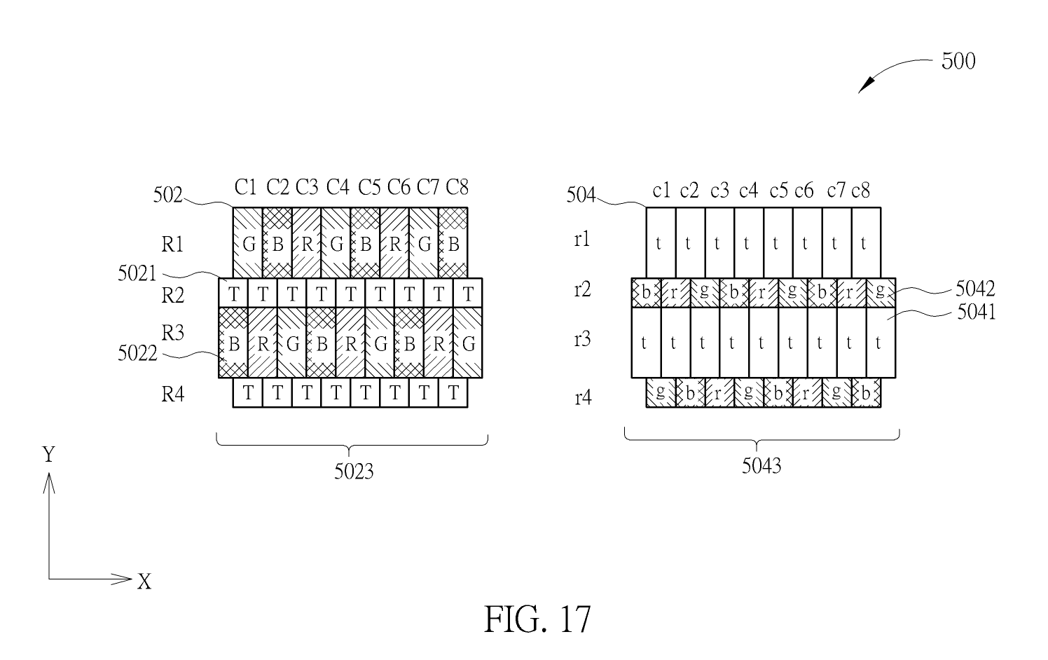

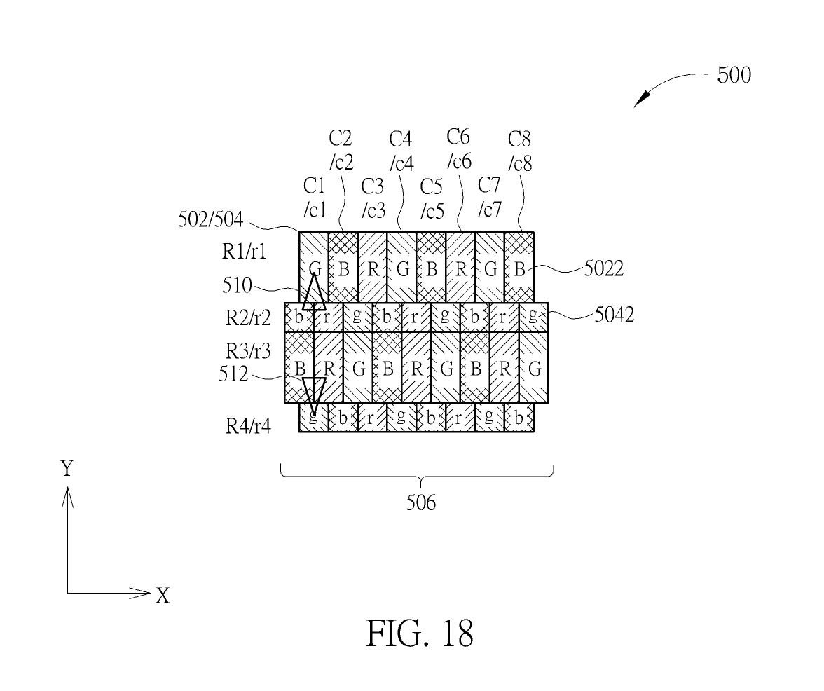

FIG. 17 to FIG. 18 are schematic diagrams of a transparent display device in a fourth variant embodiment of the fourth embodiment of the present invention. To simplify the description, the peripheral zone is shown and only a partial display zone of the transparent display panel is illustrated in FIG. 17 and FIG. 18. A transparent display device 500 of the fourth variant embodiment of the fourth embodiment includes a first transparent display panel 502 and a second transparent display panel 504, having a first display area 5023 and a second display area 5043 respectively. The first transparent display panel 502 includes a plurality of first transparent regions 5021 and a plurality of first display regions 5022, and the second transparent display panel 504 includes a plurality of second transparent regions 5041 and a plurality of second display regions 5042. However, different from the second variant embodiment of the fourth embodiment, the first transparent regions 5021 of the present variant embodiment are square and the first display regions 5022 of the present variant embodiment are rectangles, with an area of the first display regions 5022 being larger than that of the first transparent regions 5021, and the second transparent regions 5041 are rectangles and the second display regions 5042 are square, with an area of the second display regions 5042 being smaller than that of the second transparent regions 5041. Wherein, the first display regions 5022 are corresponding to the second transparent regions 5041 respectively and the first transparent regions 5021 are corresponding to the second display regions 5042. Therefore, the first transparent display panel 502 has a lower transmittance in comparison with the second transparent display panel 504 under the first display mode. In this way, the first and the second transparent display panels 502, 504 will have various transmittances, so as to obtain product with more variation. For example, the first transparent display panel 502 may be used for mainly displaying images, and the second transparent display panel 504 may be used for providing clear background seen by the viewer. Referring to FIG. 18, while the first transparent display panel 502 with the first display area 5023 and the second transparent display panel 504 with the second display area 5043 are assembled together to compose a second display device 506, any one of the second sub-pixels “G” in one of the rows (such as R1) and one of the third sub-pixels “b” and one of the first sub-pixels “r” in another adjacent row (such as r2) are arranged in a delta arrangement, such as the deltas 510, 512 shown in FIG. 18.

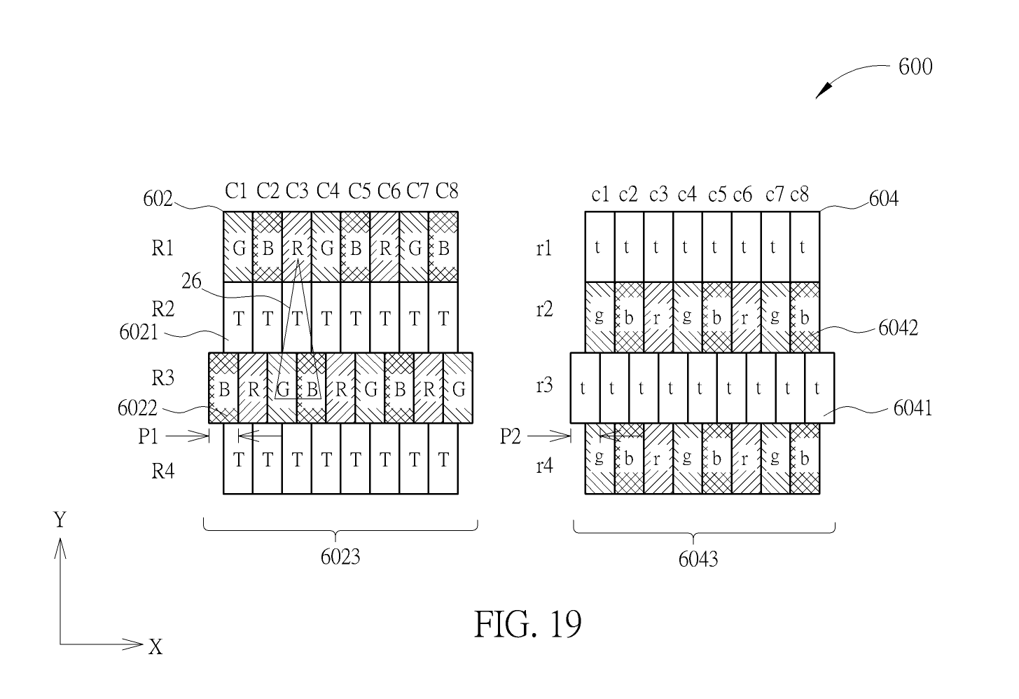

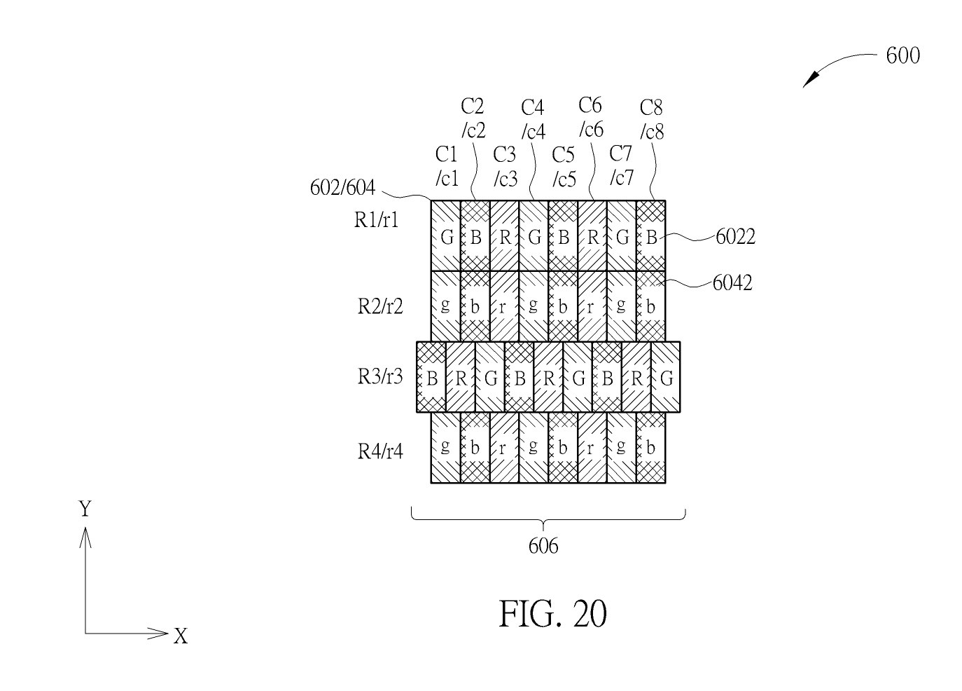

FIG. 19 to FIG. 20 are schematic diagrams of a transparent display device in a fifth variant embodiment of the fourth embodiment of the present invention. To simplify the description, the peripheral zone is not been shown and only a partial display zone of the transparent display panel is illustrated in FIG. 19 and FIG. 20. Referring to FIG. 19, a transparent display device 600 of the fifth variant embodiment of the fourth embodiment includes a first transparent display panel 602 and a second transparent display panel 604, having a first display area 6023 and a second display area 6043 respectively. The first transparent display panel 602 includes a plurality of first transparent regions 6021 and a plurality of first display regions 6022, and the second transparent display panel 604 includes a plurality of second transparent regions 6041 and a plurality of second display regions 6042. Different from the second variant embodiment of the fourth embodiment of the present invention, the present variant embodiment is characterize in that two adjacent first rows R1 and R3 of the first transparent display panel 602 are shifted=with a distance of half a width P1 of the first display regions 6022 while the first transparent regions 6021 of the second rows R2, R4 are all aligned with the first display regions 6022 of the first row R1, and the first display regions 6022 of the first row R3 also have a shift relative to the first transparent regions 6021 of the adjacent second rows R2, R4 in a half of the width P1 of the first display regions 6022. The first sub-pixels “R”, the second sub-pixels “G” and the third sub-pixel “B” in any two adjacent first rows R1, R3 are arranged in a delta arrangement. For example, one of the first sub-pixels “R” in the first row R1 and one of the second sub-pixels “G” and one of the third sub-pixels “B” in the adjacent first row R3 are arranged in a delta 26 arrangement. Likewise, two adjacent third rows r1 and r3 of the second transparent display panel 604 are shifted to each other, with the third row r3 spacing to the third row r1 in a distance of half a width P2 of the second transparent regions 6041, but the second display regions 6042 of the fourth rows r2, r4 are all aligned with the second transparent regions 6041 of the third row r1. In addition, the second transparent regions 6041 of the third row r3 also have a shifted distance to the second display regions 6042 of the adjacent fourth rows r2, r4 in a distance of half the width P2 of the second transparent regions 6041. As shown in FIG. 20, the first transparent display panel 602 and the second transparent display panel 604 can be assembled to compose a second display device 606 by overlapping the first transparent display panel 602 and the second transparent display panel 604, wherein the first transparent regions 6021 are corresponding with the second display regions 6042 respectively, and the first display regions 6022 are corresponding with the second transparent regions 6041 respectively.

In comparison with prior arts, the transparent display panel of the present invention has transparent regions and display regions organized in a particular arrangement, thereby providing preferable transmittance and obtaining highly defined display images with a high resolution. Furthermore, the transparent display device of the present invention includes at least one first transparent display panel and one second transparent display panel, with each of them including transparent regions and display regions, however disposed oppositely in the first transparent display panel and the second transparent display panel respectively. Accordingly, by adjusting the relative position of the first and the second transparent display panels, the transparent display device of the present invention can switch from the first display mode to the second display mode. It means that different kind of display modes can be chosen. While switching to the second display mode, the first and the second transparent display panels at least are partially overlapped with each other to provide a pixel arrangement with a better resolution, thereby displaying clear but nontransparent images and clearly displaying animation and films. On the other hand, in the first display mode, the transparent display device of the present invention also can provide images with high transmittance. In various embodiments, the transparent display device of the present invention further includes more than two transparent display panels, resulting in more flexible and various applications. Additionally, since the transparent display panel of the present invention has the first, the second and the third sub-pixels arranged in a delta arrangement, it is sufficient to achieve a preferable resolution relatively, and also to provide highly defined images by further shortening a size of each pixel via the shifted arrangement of the sub-pixels.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A transparent display panel, comprising:
a plurality of transparent regions and a plurality of display regions arranged in the transparent display panel, the transparent regions and the display regions being arranged alternately along a first direction;
a plurality of first sub-pixels, a plurality of second sub-pixels and a plurality of third sub-pixels, each of the first sub-pixels, the second sub-pixels and the third sub-pixels being disposed in each one of the display regions respectively, the first sub-pixels being used for generating a first primary color light, the second sub-pixels being used for generating a second primary color light, and the third sub-pixels being used for generating a third primary color light, wherein the first sub-pixels, the second sub-pixels and the third sub-pixels are disposed alternately in the corresponding display regions of the transparent display panel along a second direction, and the first direction intersects the second direction,
wherein the display regions and the transparent regions are arranged in a plurality of rows extending along the second direction, and one of the first sub-pixels, one of the second sub-pixels and one of the third sub-pixels adjacent to each other in the transparent display panel are arranged in a shape of delta arrangement.

2. The transparent display panel of claim 1, wherein in each of the rows extending along the second direction, the display regions and the transparent regions are arranged alternately.

3. The transparent display panel of claim 2, wherein in each of the rows extending along the second direction, the first sub-pixels, the second sub-pixels and the third sub-pixels are disposed alternately in the display regions along the second direction.

4. The transparent display panel of claim 3, wherein the display regions and the transparent regions are arranged in a plurality of columns extending along the first direction, and the display regions and the transparent regions are arranged alternately in each of the columns extending along the first direction.

5. The transparent display panel of claim 4, wherein only one kind of the first sub-pixels, the second sub-pixels and the third sub-pixels are disposed in the display regions in one single column of the columns extending along the first direction.

6. The transparent display panel of claim 1, wherein any one of the display regions is adjacent to at least two of the transparent regions and is not adjacent to the other display regions, and any one of the transparent regions is adjacent to at least two of the display regions and is not adjacent to the other transparent regions.

7. The transparent display panel of claim 1, wherein the display regions are arranged in a plurality of first rows extending along the second direction, the transparent regions are arranged in a plurality of second rows extending along the second direction, and the first rows and the second rows are alternately arranged along the first direction.

8. The transparent display panel of claim 7, wherein any one of the first sub-pixels in one of the first rows and one of the second sub-pixels and one of the third sub-pixels in another one of the first rows adjacent to the first sub-pixel are arranged delta arrangement.

9. The transparent display panel of claim 7, wherein the display regions have a width and the display regions in one of the first rows are arranged by a shift in a half of the width relative to the display regions in another first row adjacent to the one of the first rows.

10. The transparent display panel of claim 1, wherein the display regions and the transparent regions are in rectangle shapes respectively.

11. The transparent display panel of claim 1, wherein the display regions and the transparent regions are in square shapes respectively.

12. A transparent display device, comprising:
at least one first display panel, including a plurality of first transparent regions and a plurality of first display regions, the first transparent regions and the first display regions being arranged alternately in a plurality of rows or columns extending at least along a first direction, and the first display panel having a first display area; and
at least one second display panel, including a plurality of second transparent regions and a plurality of second display regions, the second transparent regions and the second display regions being arranged alternately in a plurality of rows or columns extending at least along the first direction, and the second display panel having a second display area,
wherein in a first display mode, the first display panel and the second display panel compose a first display device having a third display area by being disposed in parallel and side by side, thereby displaying a full image with the third display area which is approximately equal to a sum of the first display area and the second display area, and
in a second display mode, the first display panel and the second display panel compose a second display device having a fourth display area by being overlapped with each other, wherein each of the display regions of the first display panel is corresponding to one of the transparent regions of the second display panel respectively, each of the transparent regions of the first display panel is corresponding to one of the display regions of the second display panel respectively, and the fourth display area is approximately equal to an overlapping area of the first display area and the second display area.

13. The transparent display device of claim 12, further including a slide mechanism disposed on at least one of the first display panel and the second display panel such that one of the first display panel and the second display panel disposed arranged in parallel and side by side is capable of being moved to a surface of the other one of the first display panel and the second display panel through the slide mechanism to compose the second display device.

14. The transparent display device of claim 12, further including a pivot mechanism disposed between the first display panel and the second display panel such that one of the first display panel and the second display panel disposed in parallel and side by side is capable of turning over on a surface of the other one of the first display panel and the second display panel through the pivot mechanism to compose the second display device.

15. The transparent display device of claim 12, wherein at least one of the first display panel and the second display panel is a double-side light-emitting display panel.

16. The transparent display device of claim 12, further including a plurality of the second display panels, wherein the first display area is greater than each of the second display areas, when the second display panels and the first display panel compose the second display device, the second display panels are disposed in parallel and side by side at a side of the first display panel, and the fourth display area is approximate equal to the first display area.

17. The transparent display device of claim 16, wherein the first display area is equal to a sum of all of the second display areas.

18. The transparent display device of claim 12, wherein the first display area is approximate equal to the second display area.

19. The transparent display device of claim 12, wherein the first display panel further includes a plurality of first sub-pixels, a plurality of second sub-pixels and a plurality of third sub-pixels, each of the first, second and third sub-pixels is disposed in the first display regions respectively, and the second display panel further includes a plurality of first sub-pixels, a plurality of second sub-pixels and a plurality of third sub-pixels, each of the first, second and third sub-pixels is disposed in the second display regions respectively, the first sub-pixels of the first display panel and the second display panel are used for generating a first primary color light, the second sub-pixels of the first display panel and the second display panel are used for generating a second primary color light, and the third sub-pixels of the first display panel and the second display panel are used for generating a third primary color light.

20. The transparent display device of claim 19, wherein the first sub-pixels, the second sub-pixels and the third sub-pixels of the first display panel are respectively arranged in a plurality of columns extending along a second direction that intersects the first direction and the first sub-pixels, the second sub-pixels and the third sub-pixels are arranged alternately along the first direction, and the second sub-pixels, the third sub-pixels and the first sub-pixels of the second display panel are respectively arranged in a plurality of columns extending along the second direction and the second sub-pixels, the third sub-pixels and the first sub-pixels are arranged alternately along the first direction, such that when the first display panel and the second display panel are overlapped to compose the second display device, the first sub-pixels, the third sub-pixels and the second sub-pixels of the first display panel and the second display panel are arranged alternately along the first direction.

21. The transparent display device of claim 19, wherein in the first display panel, the first transparent regions and the first display regions are arranged alternately and side by side in a plurality of columns extending along the second direction, the first display regions in each of the columns extending along the second direction include only one kind of the first sub-pixels, the second sub-pixels and the third sub-pixels respectively, and the first sub-pixels, the second sub-pixels and the third sub-pixels being arranged alternately along the first direction; and
in the second display panel, the second display regions and the second transparent regions are arranged alternately and side by side in a plurality of columns extending along the second direction, the second display regions in each of the columns extending along the second direction include only one kind of the first sub-pixels, the second sub-pixels and the third sub-pixels respectively, and the first sub-pixels, the second sub-pixels and the third sub-pixels being arranged alternately along the first direction.

22. The transparent display device of claim 21, wherein in the first display panel, any one of the first transparent regions is adjacent to at least two of the first display regions but not adjacent to any other first transparent regions, and in the second display panel, any one of the second transparent regions is adjacent to at least two of the second display regions but not adjacent to other second transparent regions.

23. The transparent display device of claim 19, wherein
in the first display panel, the first display regions are arranged side by side in a plurality of first rows along a second direction, the first transparent regions are arranged side by side in a plurality of the second rows along the second direction, and the first rows and the second rows are arranged alternately along the first direction, wherein the first sub-pixels, the second sub-pixels and the third sub-pixels are sequentially and alternately arranged along the second direction in each of the first rows, and any one of the first sub-pixels in one of the first rows and one of the second sub-pixels and one of the third sub-pixels adjacent to the first sub-pixel in another one of the first rows are arranged in a delta arrangement; and
in the second display panel, the second transparent regions are arranged side by side in a plurality of third rows along the second direction, the second display regions are arranged side by side in a plurality of fourth rows along the second direction, and the third rows and the fourth rows are arranged alternately along the first direction, wherein the first sub-pixels, the second sub-pixels and the third sub-pixels are sequentially and alternately arranged along the second direction in each of the fourth rows, and any one of the first sub-pixels in one of the fourth rows and one of the second sub-pixels and one of the third sub-pixels adjacent to the first sub-pixels in another one of the fourth rows are arranged in a delta arrangement;
wherein when the first display panel and the second display panel compose the second display device, the fourth rows and the first rows are arranged alternately along the first direction, and any one of the first sub-pixels in one of the first rows and one of the second sub-pixels and one of the third sub-pixels adjacent to the first sub-pixels in one of the fourth rows adjacent to the first rows are arranged in a delta arrangement.

24. The transparent display device of claim 23, wherein the first display regions have a first width, the second display regions have a second width, the first display regions in any one of the first rows are arranged by a shift in a half of the first width relative to the first display regions in another adjacent first rows, and the second display regions in any one of the fourth rows are arranged by a shift in a half of the second width relative to the second display regions in another adjacent fourth rows.

25. The transparent display device of claim 12, wherein the first display regions, the first transparent regions, the second display regions and the second transparent regions are in rectangle shapes respectively.

26. The transparent display device of claim 12, wherein the first display regions, the first transparent regions, the second display regions and the second transparent regions are in square shapes respectively.

27. The transparent display device of claim 12, wherein not all of the first display regions, the first transparent regions, the second display regions and the second transparent regions have identical shapes.

28. The transparent display device of claim 27, wherein an area of each of the first display regions is greater than an area of each of the first transparent regions and an area of each of the second display regions is smaller than an area of each of the second transparent regions.
